(19) United States
(12) Patent Application Publication
(10) Pub. No.: US 2026/0282769 A1
(43) Pub. Date: Sep. 17, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventor: Hui-Lin Wang, Taipei City (TW)

(73) Assignee: UNITED MICROELECTRONICS CORP., Hsin-Chu City (TW)

(21) Appl. No.: 19/180,113

(22) Filed: Apr. 15, 2025

(30) Foreign Application Priority Data
Mar. 17, 2025 (TW) 114109859

(51) Int. Cl. H10N 70/00; H10B 63/00

(52) U.S. Cl. CPC H10N 70/8833; H10B 63/30; H10N 70/826; H10N 70/841

(57) ABSTRACT

A resistive random access memory (RRAM) includes an interlayer dielectric (ILD) layer on a substrate, a contact plug in the ILD layer, a bottom electrode on the contact plug, a resistor switching layer on the bottom electrode, and a capping layer on the resistor switching layer. Preferably, the capping layer includes more than one capping layer and the more than one capping layer includes ruthenium oxide (RuO₂).

### BACKGROUND OF THE INVENTION

### 1. Field of the Invention

The invention relates to a semiconductor device, and more particularly to a resistive random access memory (RRAM) device.

### 2. Description of the Related Art

Non-volatile memory devices have the advantages of retaining data even if the electrical power is being cut off, hence non-volatile memory devices have been widely used in most appliances today for maintaining proper operation of the electronic products. Currently, a popular non-volatile memory device being developed today is referred to as resistive random access memory (RRAM), which has the advantages of low voltage and short erase time under write operation, long memory duration, no damage under read operation, multiphase memory, simple structure, and small size. With all these benefits, RRAM devices are likely to be used in various personal computers and electronic equipment in the coming future.

In integrated circuits, RRAM is a merging technology applied for the next generation non-volatile memory devices. Specifically, RRAM is a memory structure having a resistive random access memory array, in which each of the resistive random access memory units uses resistance values to store one bit of data instead of electrical potentials. In particular, each of the resistive random access memory units include a resistance material layer that could be used to adjust resistance value for demonstrating “0” or “1”.

One approach to optimize RRAM array is to minimize its size as much as possible. Nevertheless, as size of the device decrease, fabrication cost and complexity also increase accordingly. Hence, how to lower the overall cost while maintaining yield of the product has become a major challenge in this field.

### SUMMARY OF THE INVENTION

According to an embodiment of the present invention, a resistive random access memory (RRAM) includes an interlayer dielectric (ILD) layer on a substrate, a contact plug in the ILD layer, a bottom electrode on the contact plug, a resistor switching layer on the bottom electrode, and a capping layer on the resistor switching layer. Preferably, the capping layer includes more than one capping layer and the more than one capping layer includes ruthenium oxide (RuO₂).

According to another aspect of the present invention, a resistive random access memory (RRAM) includes an interlayer dielectric (ILD) layer on a substrate, a contact plug in the ILD layer, a bottom electrode on the contact plug, a resistor switching layer on the bottom electrode, and a capping layer on the resistor switching layer. Preferably, the capping layer includes ruthenium oxide (RuO₂) having a gradient concentration of oxygen.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a semiconductor device according to an embodiment of the present invention.

FIG. 8 illustrates a structural view of a semiconductor device according to an embodiment of the present invention.

FIG. 9 illustrates a structural view of a semiconductor device according to an embodiment of the present invention.

FIG. 10 illustrates a structural view of a semiconductor device according to an embodiment of the present invention.

FIG. 11 illustrates a structural view of a semiconductor device according to an embodiment of the present invention.

FIG. 12 illustrates a structural view of a semiconductor device according to an embodiment of the present invention.

### DETAILED DESCRIPTION

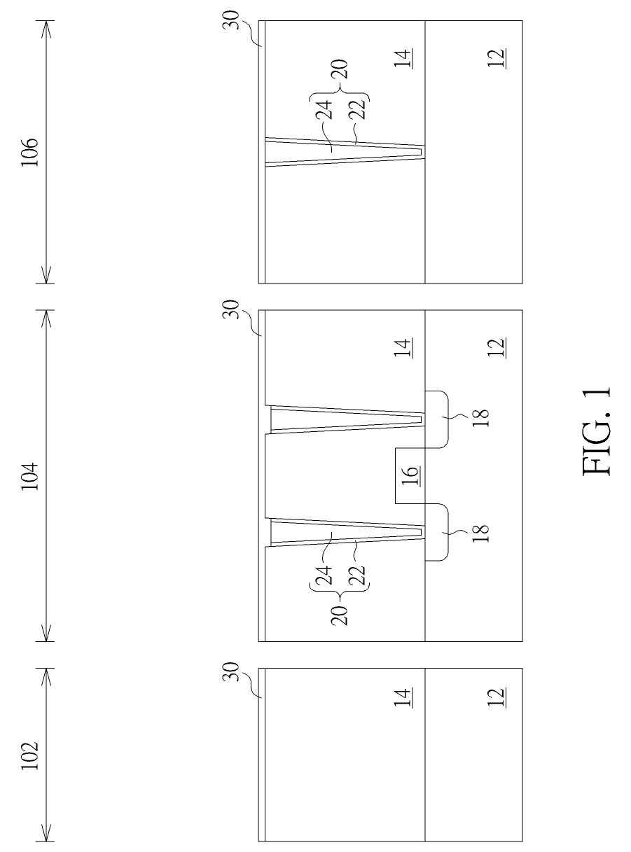

Referring to FIGS. 1-7, FIGS. 1-7 illustrate a method for fabricating a semiconductor device, or more specifically a RRAM device according to an embodiment of the present invention. As shown in FIG. 1, a substrate 12 made of semiconductor material is first provided, in which the semiconductor material could be selected from the group consisting of silicon (Si), germanium (Ge), Si-Ge compounds, silicon carbide (SiC), and gallium arsenide (GaAs), and an alignment mark (AM) region 102, a RRAM region 104, and a logic region 106 are defined on the substrate 12.

Active devices such as metal-oxide semiconductor (MOS) transistors, passive devices, conductive layers, and interlayer dielectric (ILD) layer 14 could also be formed on top of the substrate 12 on both RRAM region 104 and logic region 106. More specifically, planar MOS transistors or non-planar (such as FinFETs) MOS transistors could be formed on the substrate 12, in which the MOS transistors could include transistor elements such as gate structures 16 (for example metal gates) and source/drain regions 18, spacer, epitaxial layer, and contact etch stop layer (CESL). The ILD layer 14 could be formed on the substrate 12 to cover the MOS transistors, and a plurality of contact plugs 20 could be formed in the ILD layer 14 to electrically connect to the gate structures 16 and/or source/drain regions 18 of MOS transistors. Since the fabrication of planar or non-planar transistors and ILD layer is well known to those skilled in the art, the details of which are not explained herein for the sake of brevity.

In this embodiment, the formation of the contact plugs 20 could be accomplished by first conducting a pattern transfer process by using a patterned mask (not shown) as mask to remove part of the ILD layer 14 on the memory region 102 and logic region 104 for forming contact holes (not shown) exposing the source/drain regions 18 underneath. Next, metal or conductive materials including a barrier layer 22 selected from the group consisting of titanium (Ti), titanium nitride (TiN), tantalum (Ta), and tantalum nitride (TaN) and a metal layer 24 selected from the group consisting of tungsten (W), copper (Cu), aluminum (Al), titanium aluminide (TiAl), and cobalt tungsten phosphide (CoWP) are deposited into the contact holes, and then a planarizing process such as chemical mechanical polishing (CMP) process is conducted to remove part of the metal for forming contact plugs 20 or metal interconnections in the contact holes electrically connecting the source/drain regions 18.

Next, another pattern transfer process could be conducted by using a patterned mask to remove part of the contact plugs 20 for forming a recess directly on top of each contact plug 20 while the top surface of the remaining contact plugs 20 is slightly lower than the top surface of the ILD layer 14 on two adjacent sides. Next, a bottom electrode (BE) 30 is formed on the ILD layer 14 on the AM region 102, the RRAM region 104, and the logic region 106 and filling the recesses directly atop the contact plugs 20 completely. In this embodiment, the bottom electrode 30 is made of metal nitride such as tantalum nitride (TaN) and the thickness thereof is between 100-200 Angstroms.

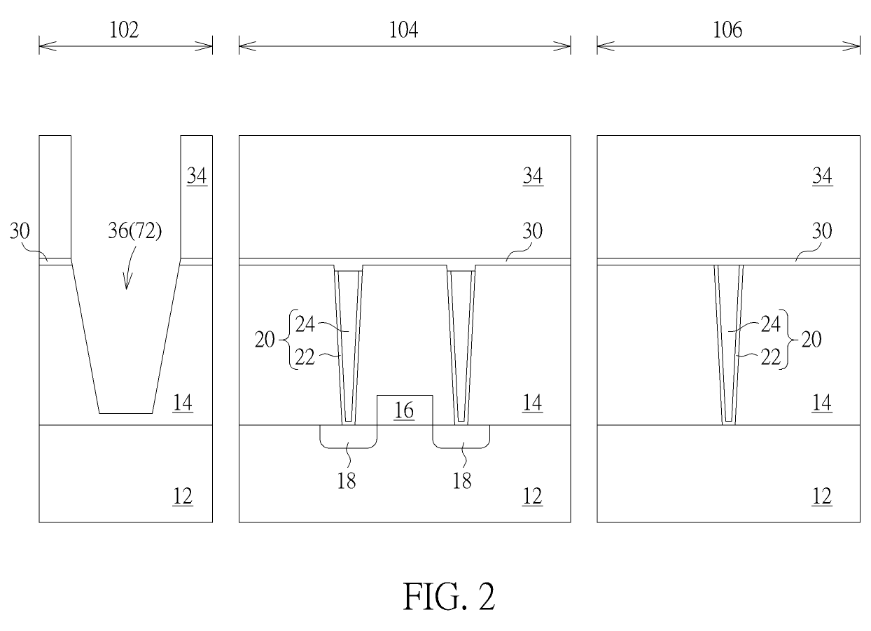

Next, as shown in FIG. 2, a patterned mask 34 such as patterned resist is formed on the bottom electrode 30 of the AM region 102, the RRAM region 104, and the logic region 106, in which the patterned mask 34 includes an opening exposing the surface of the bottom electrode 30 on the AM region 102. Next, an etching process is conducted by using the patterned mask 34 as mask to remove part of the bottom electrode 30 and part of the ILD layer 14 on the AM region 102 for forming a trench 36, in which the trench 36 could be used as an alignment mark 72 on the AM region 102 in the later process.

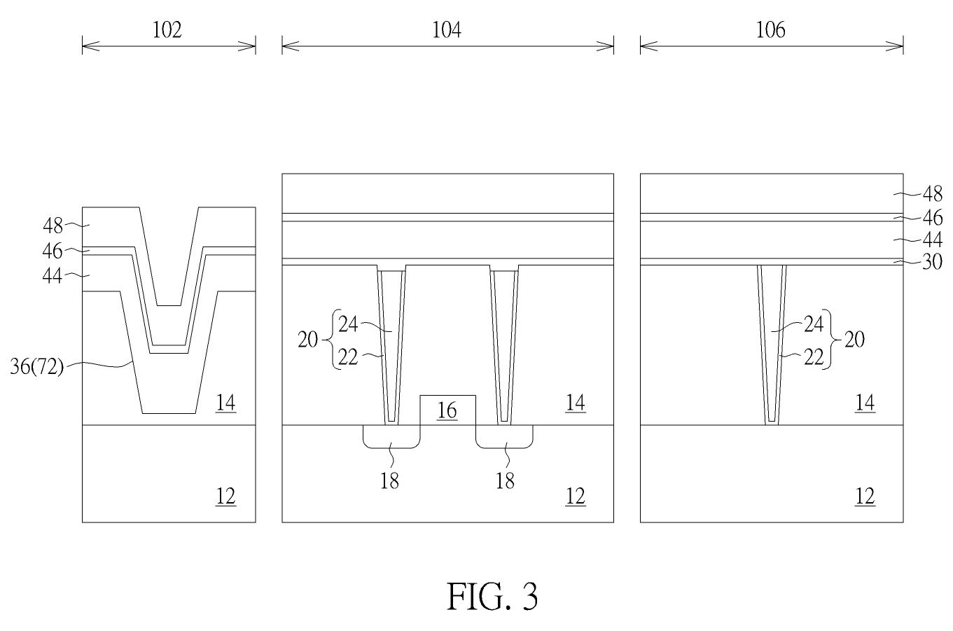

Next, as shown in FIG. 3, the patterned mask 34 is stripped by oxygen gas to expose the bottom electrode 30 once more, and then a resistor switching layer 44, a capping layer 46, and a top electrode (TE) 48 are formed on the surface of bottom electrode 30. In this embodiment, the resistor switching layer 44 preferably includes a metal nitride layer such as TaO or hafnium oxide (HfO₂), the capping layer 46 includes a metal oxide layer such as ruthenium oxide (RuO₂), and the top electrode 48 includes metal nitride such as metal nitride or metal oxide such as tantalum nitride (TaO) or TiN. Preferably, the capping layer 46 is made of a single layer structure not including gradient concentration of oxygen. In other words, any spot within the capping layer 46 has equal oxygen content or concentration or that the oxygen concentration of the entire layer is evenly distributed.

It should be noted that after the patterned mask 34 is stripped and before the resistor switching layer 44 is formed, a selective pre-clean process could be conducted by using argon (Ar) plasma to remove metal oxide layer formed during stripping of the patterned mask 34, and then a planarizing process such as chemical mechanical polishing (CMP) process is conducted to remove part of the bottom electrode 30 on the AM region 102, the RRAM region 104, and the logic region 106. The thickness of the bottom electrode 30 remained after the planarizing process is between 50-100 Angstroms.

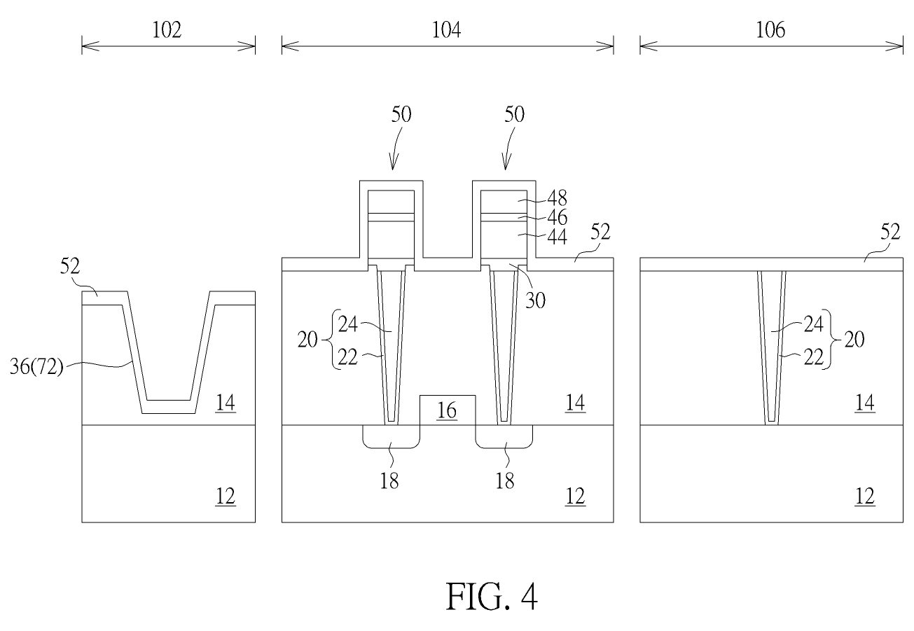

Next, as shown in FIG. 4, one or more etching processes could be conducted by using a patterned mask (not shown) as mask to remove all the top electrode 48, all the capping layer 46, all the resistor switching layer 44, and all the bottom electrode 30 on the AM region 102 and logic region 106 and part of the top electrode 48, part of the capping layer 46, part of resistor switching layer 44, and part of the bottom electrode 30 on the RRAM region 104. This exposes the surface of the ILD layer 14 on the AM region 102 and logic region 106 and forms a RRAM 50 made of patterned bottom electrode 30, patterned resistor switching layer 44, patterned capping layer 46, and patterned top electrode 48 on the RRAM region 104. Next, a cap layer 52 is formed on the surface of the ILD layer 14 and into the trench 36 on the AM region 102, surface of the ILD layer 14 and RRAM 50 on the RRAM region 104, and surface of the ILD layer 14 on the logic region 106. Preferably, the cap layer 52 includes dielectric material such as silicon oxycarbide (SiOC), silicon carbon nitride (SiCN), or silicon nitride (SiN) and the etching process conducted for forming the aforementioned RRAM 50 during patterning process could include reactive ion etching (RIE) or ion beam etching (IBE) process, but not limited thereto.

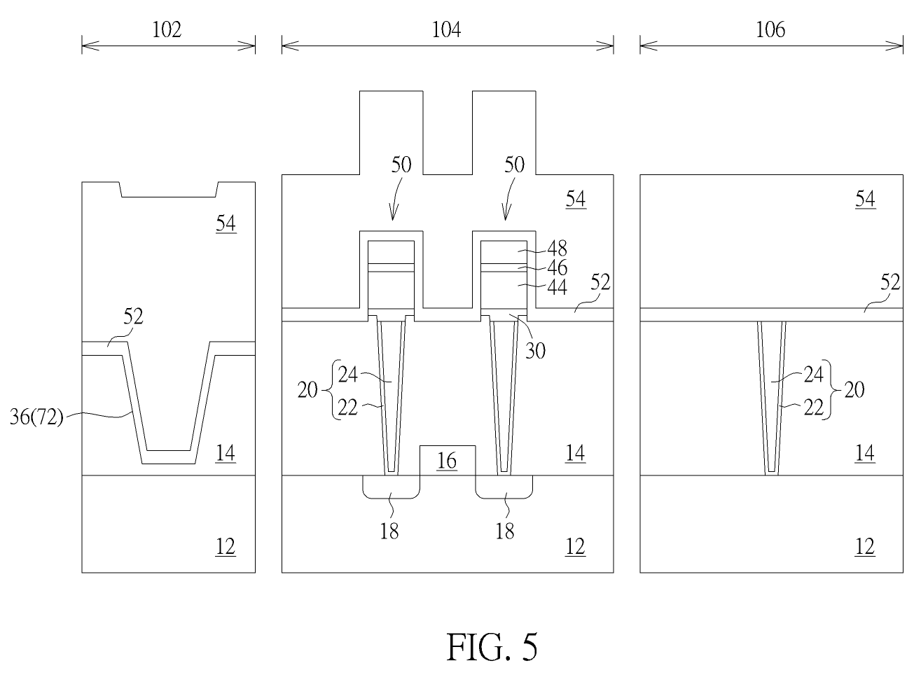

Next, as shown in FIG. 5, a flowable chemical vapor deposition (FCVD) process could be conducted to form an inter-metal dielectric (IMD) layer 54 on ILD layer 14 on the AM region 102, the RRAM region 104, and the logic region 106 to fill the trench 36 completely and cover the RRAM 50. In this embodiment, the IMD layer 54 is preferably made of silicon oxide or ultra low-k (ULK) dielectric layer including but not limited to for example porous material or silicon oxycarbide (SiOC) or carbon doped silicon oxide (SiOCH).

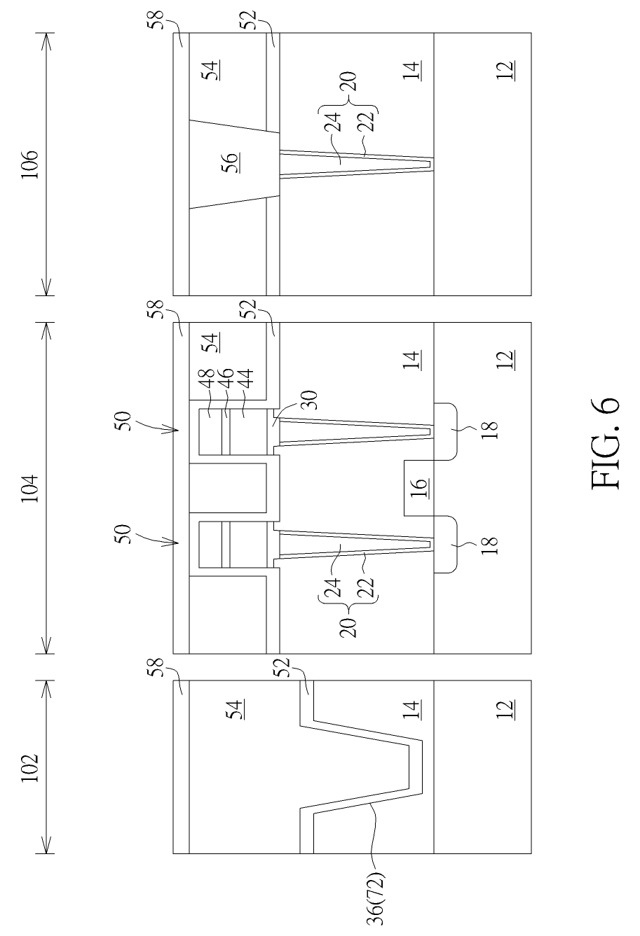

Next, as shown in FIG. 6, a planarizing process such as CMP is conducted to remove part of the IMD layer 54 on the AM region 102, RRAM region 104, and logic region 106 so that the top surfaces of the IMD layer 54 and the cap layer 52 on the RRAM region 104 are coplanar.

Next, a patterned transfer process could be conducted by using a patterned mask (not shown) as mask to remove part of the IMD layer 54 and part of the cap layer 52 on the and logic region 106 for forming a contact hole (not shown) exposing the contact plug 20 underneath. Next, metal or conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact hole, and then a planarizing process such as CMP process is conducted to remove part of the metals for forming a contact plug or metal interconnection 56 in the contact hole electrically connecting the contact plug 20 underneath. Next, a stop layer 58 is formed on the IMD layer 54 on the AM region 102, the RRAM region 104, and the logic region 106. Preferably, the stop layer 58 is made of nitrogen doped carbide (NDC), silicon nitride, silicon carbon nitride (SiCN), silicon oxynitride (SiON), or combination thereof.

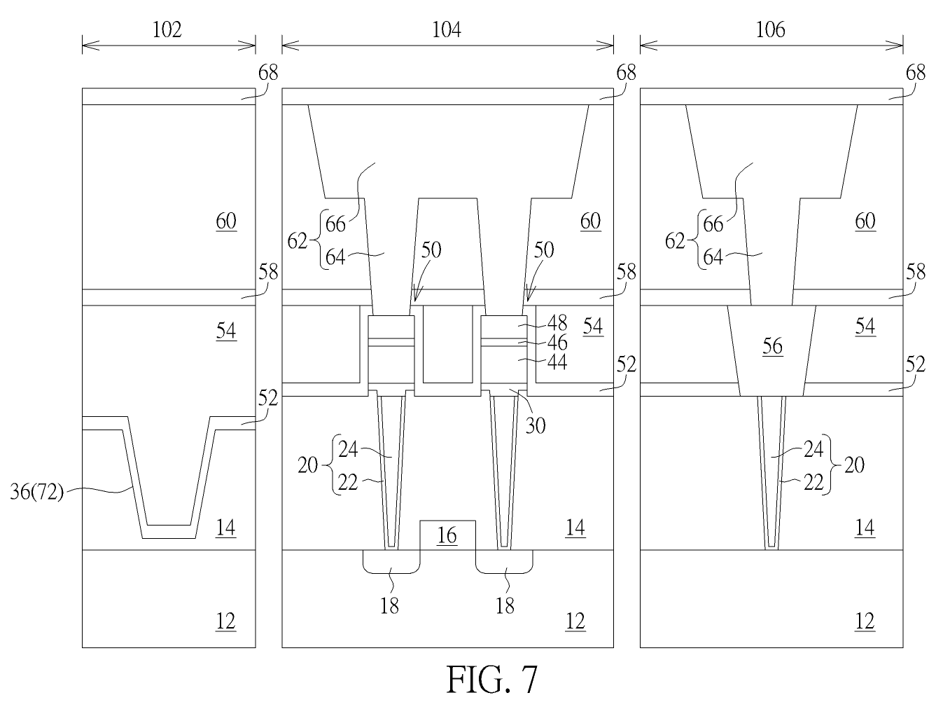

Next, as shown in FIG. 7, another IMD layer 60 is formed on the surface of the stop layer 58 and one or more photo-etching process is conducted to remove part of the IMD layer 60, part of the stop layer 58, and part of the cap layer 52 on the RRAM region 104 and logic region 106 to form contact holes (not shown) exposing the top electrode 48 and metal interconnection 56. Next, conductive materials are deposited into the contact holes and a planarizing process such as CMP is conducted to form a metal interconnection 62 connecting the top electrode 48 and metal interconnection 56 underneath, and another stop layer 68 is formed on the surface of the metal interconnections 62 thereafter. Similar to the aforementioned metal interconnection 56, the metal interconnections 62 could be embedded within the IMD layer 60 according to a single damascene process or dual damascene process. For instance, each of the metal interconnections 62 on the RRAM region 104 and logic region 106 could further include via conductors 64 connecting the RRAM 50 and metal interconnection 56 underneath and a trench conductor 66 atop the via conductors 64. Moreover, each of the metal interconnections 62 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP).

In this embodiment, the IMD layer 60 preferably include an ultra low-k (ULK) dielectric layer including but not limited to for example porous material or silicon oxycarbide (SiOC) and the stop layer 68 preferably includes nitrogen doped carbide (NDC), silicon nitride (SiN), silicon carbon nitride (SiCN), or combination thereof and most preferably includes SiN. This completes the fabrication of a semiconductor device according to an embodiment of the present invention.

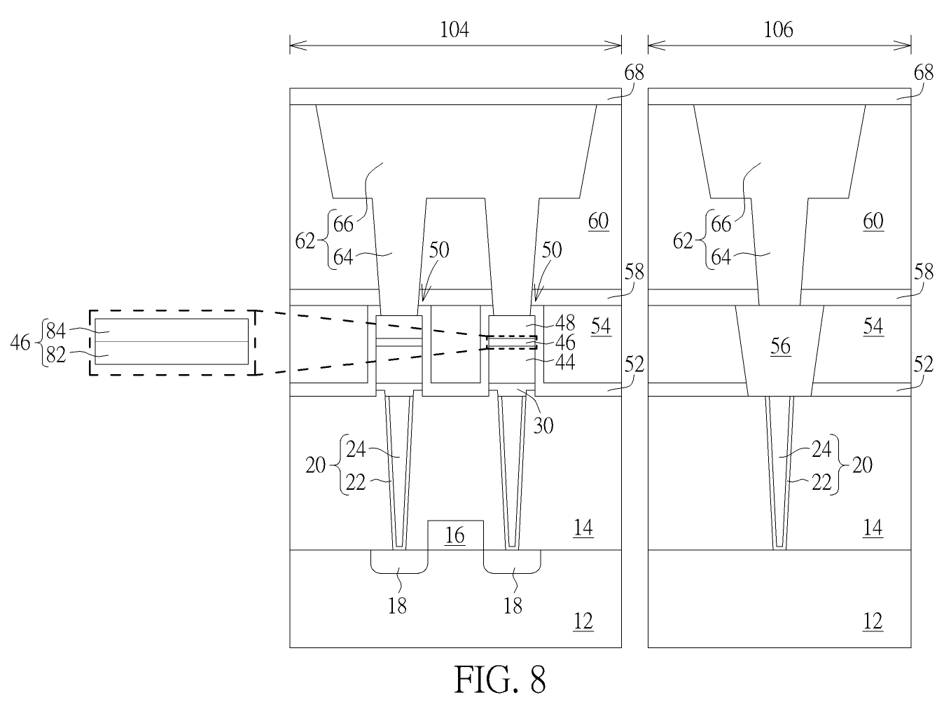

Referring to FIG. 8, FIG. 8 illustrates a structural view of a semiconductor device according to an embodiment of the present invention. For simplicity purpose and to emphasize various embodiment of the capping layer 46, elements on the AM region 102 are omitted in this embodiment and embodiments afterwards. As shown in FIG. 8, in contrast to the capping layer 46 from the previous embodiment is made of a single layer structure, the capping layer 46 could also be made of more than one layer such as a dual layer structure made of a first capping layer 82 and a second capping layer 84, in which the bottom first capping layer 82 directly contacting the resistor switching layer 44 includes metal oxide such as RuO₂, the top second capping layer 84 directly contacting the top electrode 48 includes metal such as Ru, the first capping layer 82 and the second capping layer 84 could include same thickness or different thickness, and the first capping layer 82 preferably includes no gradient concentration of oxygen. In other words, any spot within the first capping layer 82 has equal concentration of oxygen or that the oxygen concentration of the entire layer is evenly distributed.

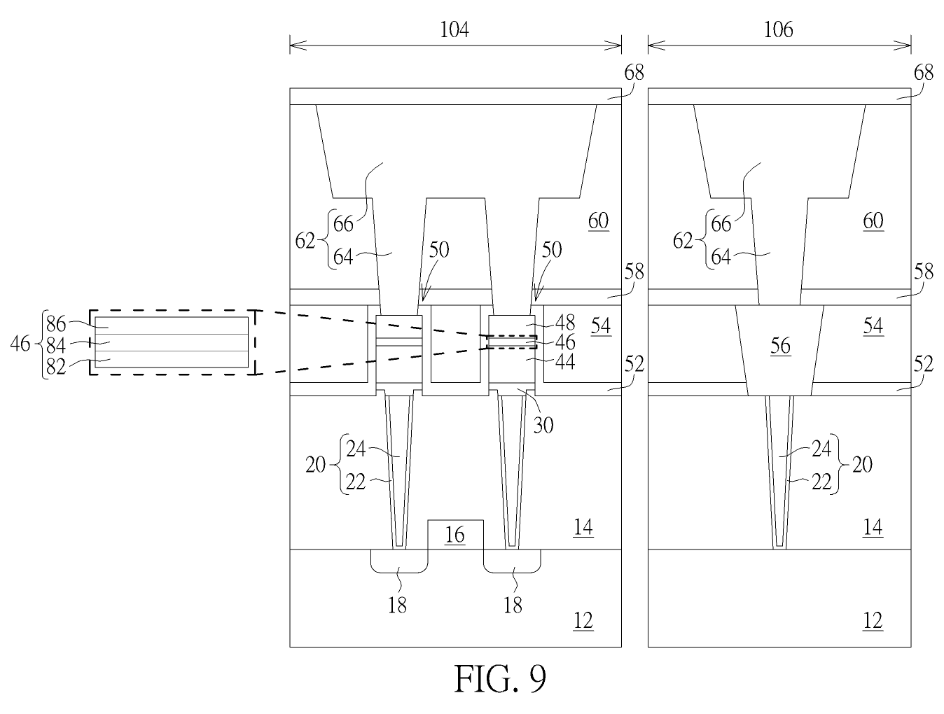

Referring to FIG. 9, FIG. 9 illustrates a structural view of a semiconductor device according to an embodiment of the present invention. As shown in FIG. 9, in contrast to the capping layer 46 in the aforementioned embodiments are made of a single layer or dual layer structure, the capping layer 46 could also be made of a triple layer structure including a first capping layer 82 disposed on the resistor switching layer 44, a second capping layer 84 disposed on the first capping layer 82, and a third capping layer 86 disposed on the second capping layer 84. In this embodiment, the bottom first capping layer 82 directly contacting the resistor switching layer 44 includes metal oxide such as RuO₂, the middle second capping layer 84 includes metal such as Ru, and the top third capping layer 86 directly contacting the top electrode 48 includes metal oxide such as RuO₂, in which the first capping layer 82, the second capping layer 84, and the third capping layer 86 could include same thickness or different thickness and both the first capping layer 82 and the third capping layer 86 preferably not including gradient concentration of oxygen.

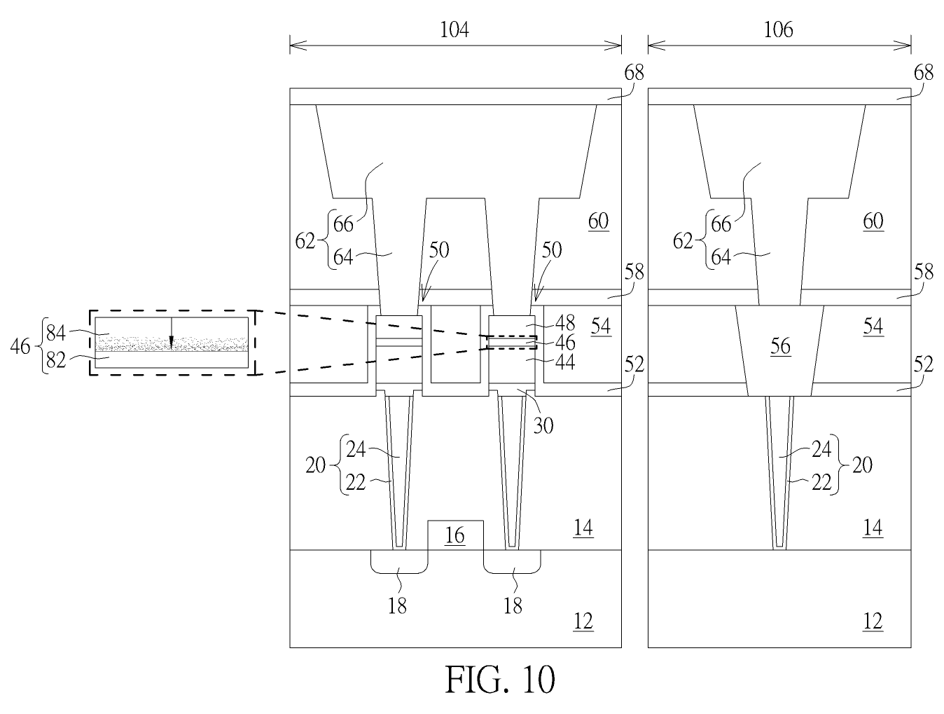

Referring to FIG. 10, FIG. 10 illustrates a structural view of a semiconductor device according to an embodiment of the present invention. As shown in FIG. 10, the capping layer 46 in this embodiment includes a first capping layer 82 and a second capping layer 84, in which the first capping layer 82 and the second capping layer 84 could include same thickness or different thickness, the bottom first capping layer 82 directly contacting the resistor switching layer 44 and the top second capping layer 84 directly contacting the top electrode 48 both include metal oxide such as RuO₂, and the first capping layer 82 includes no gradient concentration of oxygen while the second capping layer 84 includes a gradient concentration of oxygen. Specifically, the oxygen concentration in the second capping layer 84 is not evenly distributed as the oxygen concentration within the second capping layer 84 increases from top to bottom as shown by the direction of the arrow in the figure. In other words, a higher concentration of oxygen is found closer to the bottom surface of the second capping layer 84 and a lower concentration of oxygen is found closer to the top surface of the second capping layer 84, or a lower concentration of Ru is found closer to the bottom surface of the second capping layer 84 and a higher concentration of Ru is found closer to the top surface of the second capping layer 84. In this embodiment, by having higher oxygen concentration closer to the bottom surface of the second capping layer 84 could prevent RuO₂ from having reduction oxidation reaction while having higher Ru concentration closer to the top surface of the second capping layer 84 could reduce overall resistance of the device.

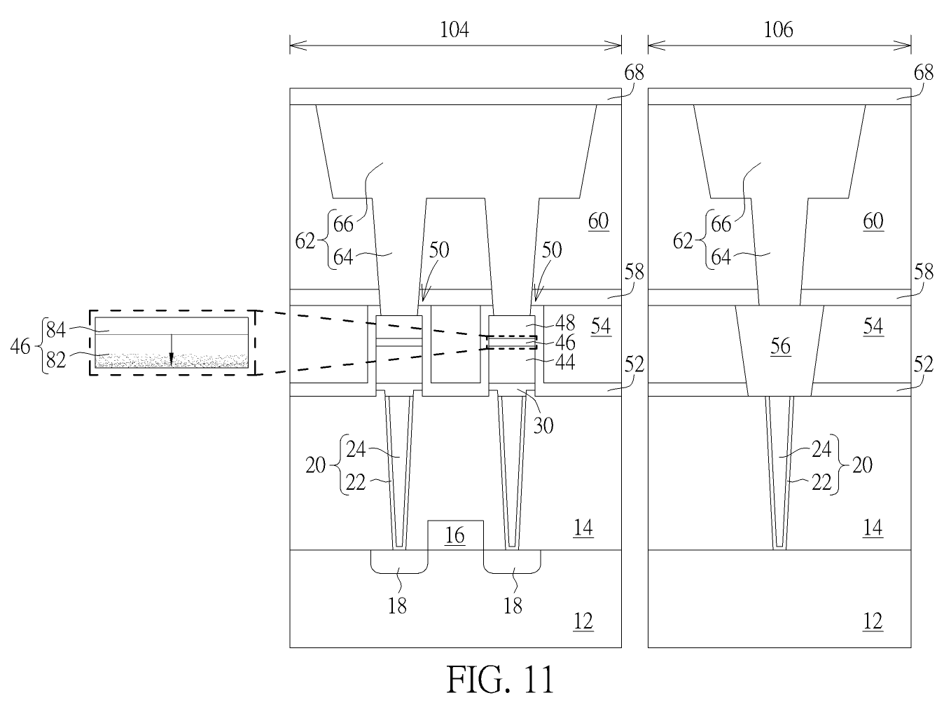

Referring to FIG. 11, FIG. 11 illustrates a structural view of a semiconductor device according to an embodiment of the present invention. As shown in FIG. 11, the capping layer 46 in this embodiment includes a first capping layer 82 and a second capping layer 84, in which the first capping layer 82 and the second capping layer 84 could include same thickness or different thickness, the bottom first capping layer 82 directly contacting the resistor switching layer 44 includes metal oxide such as RuO₂ and the top second capping layer 84 directly contacting the top electrode 48 includes metal such as Ru, and the first capping layer 82 includes a gradient concentration of oxygen. Similar to the second capping layer 84 disclosed in FIG. 10, the oxygen concentration in the first capping layer 82 of this embodiment is not evenly distributed as the oxygen concentration within the first capping layer 82 increases from top to bottom as shown by the direction of the arrow in the figure. In other words, a higher concentration of oxygen is found closer to the bottom surface of the first capping layer 82 and a lower concentration of oxygen is found closer to the top surface of the first capping layer 82, or a lower concentration of Ru is found closer to the bottom surface of the first capping layer 82 and a higher concentration of Ru is found closer to the top surface of the first capping layer 82. Similarly, by having higher oxygen concentration closer to the bottom surface of the first capping layer 82 could prevent RuO₂ from having reduction oxidation reaction while having higher Ru concentration closer to the top surface of the first capping layer 82 could reduce overall resistance of the device.

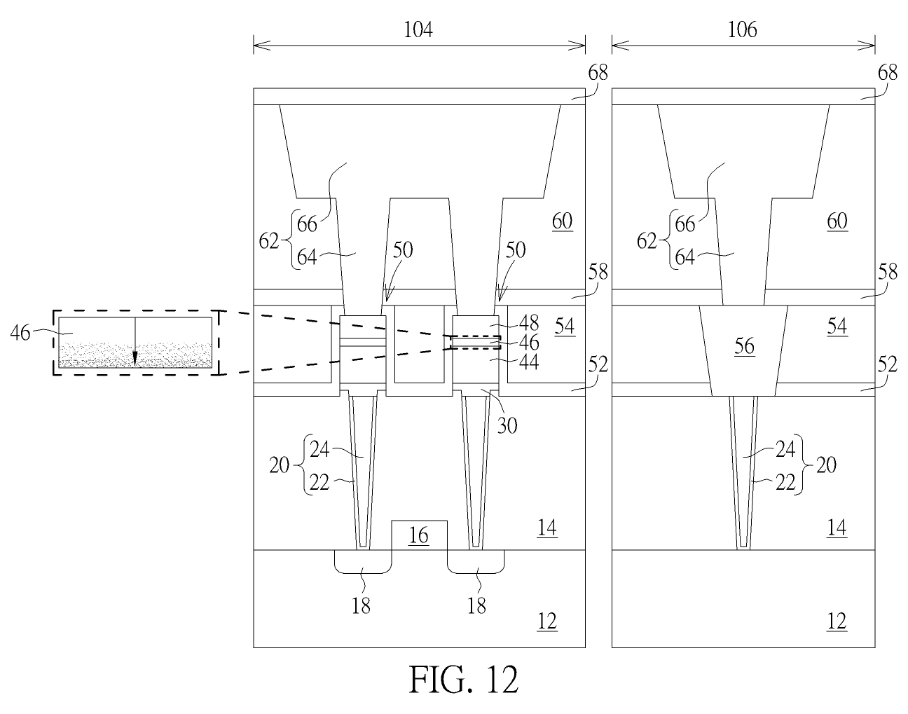

Referring to FIG. 12, FIG. 12 illustrates a structural view of a semiconductor device according to an embodiment of the present invention. As shown in FIG. 12, the capping layer 46 in this embodiment is a single layer structure, in which the bottom surface of the capping layer 46 directly contacts the resistor switching layer 44 and the top surface of the capping layer 46 directly contacts the top electrode 48, the capping layer 46 includes metal oxide such as RuO₂, and the capping layer 46 includes a gradient concentration of oxygen. Similar to the aforementioned capping layer 46 having gradient concentration of oxygen, the oxygen concentration in the capping layer 46 of this embodiment is not evenly distributed as the oxygen concentration within the capping layer 46 increases from top to bottom as shown by the direction of the arrow in the figure. In other words, a higher concentration of oxygen is found closer to the bottom surface of the capping layer 46 and a lower concentration of oxygen is found closer to the top surface of the capping layer 46, or a lower concentration of Ru is found closer to the bottom surface of the capping layer 46 and a higher concentration of Ru is found closer to the top surface of the capping layer 46.

Overall, the present invention discloses an approach for fabricating RRAM device, which first forms contact plugs 20 in an ILD layer 14 to electrically or directly connecting active devices such as source/drain regions of a MOS transistor disposed on a substrate and then forms a RRAM 50 made of a bottom electrode 30, a resistor switching layer 44, a capping layer 46, and a top electrode 48 on the contact plugs 20. Preferably, the capping layer 46 could be made of a single layer structure or multi-layer structure, the capping layer 46 preferably includes metal oxide such as such as RuO₂, and the capping layer containing RuO₂ could either include a gradient concentration of oxygen (such as the embodiments shown in FIGS. 10-12) or not including a gradient concentration of oxygen (such as the embodiments shown in FIGS. 7-9). By having metal or compound such as Ru or RuO₂ that has higher electrode potential than conventional Ta metal in the capping layer, it would be desirable to ensure that reduction oxidation reaction only takes within the capping layer and prevent titanium or nitrogen atoms from diffusing downward into the resistor switching layer thereby increasing overall performance of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A resistive random access memory (RRAM), comprising:
an interlayer dielectric (ILD) layer on a substrate;
a contact plug in the ILD layer;
a bottom electrode on the contact plug;
a resistor switching layer on the bottom electrode; and
a capping layer on the resistor switching layer, wherein the capping layer comprises more than one capping layer and the more than one capping layer comprises ruthenium oxide (RuO₂1).

2. The resistive random access memory of claim 1, wherein the capping layer comprises:
a first capping layer on the resistor switching layer; and
a second capping layer on the first capping layer.

3. The resistive random access memory of claim 2, wherein the first capping layer comprises RuO₂ and the second capping layer comprises ruthenium (Ru).

4. The resistive random access memory of claim 1, wherein the capping layer comprises:
a first capping layer on the resistor switching layer;
a second capping layer on the first capping layer; and
a third capping layer on the second capping layer.

5. The resistive random access memory of claim 4, wherein the first capping layer comprises RuO₂.

6. The resistive random access memory of claim 4, wherein the second capping layer comprises ruthenium (Ru).

7. The resistive random access memory of claim 4, wherein the third capping layer comprises RuO₂.

8. The resistive random access memory of claim 1, further comprising:
a top electrode (TE) on the capping layer;
a first inter-metal dielectric (IMD) layer around the liner;
a second IMD layer on the first IMD layer; and
a metal interconnection in the second IMD layer and connecting to the top electrode.

9. A resistive random access memory (RRAM), comprising:
an interlayer dielectric (ILD) layer on a substrate;
a contact plug in the ILD layer;
a bottom electrode on the contact plug;
a resistor switching layer on the bottom electrode; and
a capping layer on the resistor switching layer, wherein the capping layer comprises ruthenium oxide (RuO₂) having a gradient concentration of oxygen.

10. The resistive random access memory of claim 9, wherein the capping layer comprises:
a first capping layer on the resistor switching layer; and
a second capping layer on the first capping layer.

11. The resistive random access memory of claim 10, wherein the first capping layer comprises RuO₂ having no gradient concentration of oxygen.

12. The resistive random access memory of claim 10, wherein the second capping layer comprises RuO₂ having a gradient concentration of oxygen.

13. The resistive random access memory of claim 12, wherein the second capping layer comprises a higher concentration of oxygen closer to a bottom surface of the second capping layer.

14. The resistive random access memory of claim 10, wherein the first capping layer comprises RuO₂ having a gradient concentration of oxygen.

15. The resistive random access memory of claim 14, wherein the first capping layer comprises a higher concentration of oxygen closer to a bottom surface of the first capping layer.

16. The resistive random access memory of claim 10, wherein the second capping layer comprises Ru.

17. The resistive random access memory of claim 9, wherein the capping layer comprises a single layer.

18. The resistive random access memory of claim 17, wherein the capping layer comprises a higher concentration of oxygen closer to a bottom surface of the capping layer.
